(19) United States
(12) Patent Application Publication
(10) Pub. No.: US 2025/0064180 A1
(43) Pub. Date: Feb. 27, 2025

(54) LAB-GROWN DIAMOND JEWEL

(71) Applicant: Jewelry IP, LLC, New York, NY (US)

(72) Inventor: Kenneth Fogel, Millburn, NJ (US)

(73) Assignee: Jewelry IP, LLC, New York, NY (US)

(21) Appl. No.: 18/815,111

(22) Filed: Aug. 26, 2024

Related U.S. Application Data
(60) Provisional application No. 63/578,552, filed on Aug. 24, 2023.

(51) Int. Cl. A44C 17/00; A44C 1/00; C23C 16/27

(52) U.S. Cl. CPC A44C 17/007; A44C 1/00; C23C 16/27

(57) ABSTRACT

A diamond jewel is disclosed and includes a lab-grown diamond having a front surface with an outline having a shape, the front surface including a polished front face, and a rear surface parallel to the front surface, with an outline having the shape, and including a polished rear face. The diamond jewel further includes an outer surface extending between the front and rear faces and including one or more outer faces, each of the one or more outer faces being perpendicular to the front and rear faces.

### CROSS-REFERENCE TO RELATED APPLICATIONS

This application claims priority under 35 U.S.C. § 119(e) to U.S. Provisional Patent Application No. 63/578,552, filed Aug. 24, 2024. The foregoing application is incorporated by reference herein in its entirety.

### BACKGROUND OF THE INVENTION

Lab-grown diamonds are becoming an increasingly popular choice among jewelry buyers. Lab-grown diamonds are produced in a controlled technological process, typically over a period of weeks. In contrast, naturally formed diamonds were created through geological processes over billions of years and are obtained by mining. Unlike diamond simulants (imitations of diamond made of superficially similar non-diamond materials), lab-grown diamonds are composed of the same material as naturally formed diamonds—carbon crystallized in an isotropic 3D form—and share chemical composition, crystalline structure, density, hardness, refractive index, thermal conductivity, and other physical and electrical properties with mined diamonds. Some benefits of lab-grown diamond jewelry include ethical origins, sustainability, and lower prices compared to mined diamonds.

Along with High-Pressure, High-Temperature (HPHT) processes, Chemical Vapor Deposition (CVD) is a commonly used production method. Some labs start off with the less energy-intensive CVD process before finishing off the diamonds with HPHT. A third method in which nanometer-sized diamond grains are created in a detonation of carbon-containing explosives, known as detonation synthesis, entered the market in the late 1990s. A fourth method, treating graphite with high-power ultrasound, has been demonstrated in the laboratory.

Lab-grown diamonds may be treated or processed after growth to achieve configurations having novel ornamental, optical, and/or other useful properties.

### SUMMARY OF THE INVENTION

This disclosure generally relates to lab-grown diamonds and their use in jewelry. In one embodiment, a diamond jewel is disclosed. The diamond jewel includes a lab-grown diamond having a front surface with an outline having a shape, the front surface including a polished front face. The diamond jewel further includes a rear surface with an outline having the shape, the rear surface including a polished rear face, the rear surface parallel to the front surface. The diamond jewel further includes an outer surface extending between the front and rear faces, the outer surface including one or more outer faces, each of the one or more outer faces being perpendicular to the front and rear faces.

Implementations of the disclosure may include one or more of the following optional features. The synthetic diamond further includes one or more inner surfaces extending between the front and rear surfaces, the one or more inner surfaces defining a hole through the synthetic diamond, each of the one or more inner surfaces being perpendicular to adjacent front and rear surfaces. Each of the one or more inner surfaces may be parallel to at least one outer surface. The shape may include a geometric shape. The shape may include a symbol. In some examples, the synthetic diamond is free of visible imperfections. The diamond may further include a means for attaching a chain. In some examples, the synthetic diamond further includes one or more facets at a point where the front surface abuts the outer surface. The synthetic diamond may be formed by a Chemical Vapor Deposition (CVD) process. One or more outer faces may be unpolished. At least one outer face may be covered by an outer layer. The outer layer may include a precious metal. In some examples, a piece of jewelry includes the diamond jewel in a setting. The piece of jewelry may be a brooch. The one or more inner surfaces may define a heart-shaped hole.

### BRIEF DESCRIPTION OF THE DRAWINGS

The accompanying drawings, which are incorporated herein and constitute part of this specification, illustrate the presently preferred embodiments of the invention, and, together with the general description given above and the detailed description given below, serve to explain the features of the invention. In the drawings:

FIG. 1 includes a front view, a side view, an isometric view, and an oblique view of an example embodiment of the invention.

FIG. 2 includes a front view, a side view, an isometric view, and an oblique view of another example embodiment of the invention.

FIG. 3 includes a front view, a side view, an isometric view, and an oblique view of another example embodiment of the invention.

FIG. 4 includes a front view, a side view, an isometric view, and an oblique view of another example embodiment of the invention.

FIG. 5 includes a front view, a side view, an isometric view, and an oblique view of another example embodiment of the invention.

FIG. 6 includes a front view, a side view, an isometric view, and an oblique view of another example embodiment of the invention.

FIG. 7 includes a front view, a side view, an isometric view, and an oblique view of another example embodiment of the invention.

FIG. 8 includes a front view, a side view, an isometric view, and an oblique view of another example embodiment of the invention.

FIG. 9 includes a front view, a side view, an isometric view, and an oblique view of another example embodiment of the invention.

FIG. 10 includes a front view, a side view, an isometric view, and an oblique view of another example embodiment of the invention.

FIGS. 11A and 11B include front views, side views, and oblique views of other example embodiment of the invention.

FIGS. 12A and 12B include front views, side views, and oblique views of other example embodiment of the invention.

FIGS. 13A and 13B include front views, side views, and oblique views of other example embodiment of the invention.

FIG. 14 includes a front view, a side view, and an oblique view of another example embodiment of the invention.

FIG. 15 includes a front view, a side view, and an oblique view of another example embodiment of the invention.

FIG. 16 includes a front view, a side view, and an oblique view of another example embodiment of the invention.

FIG. 17 includes front and top views of another example embodiment of the invention.

### DETAILED DESCRIPTION OF THE INVENTION

In the drawings, like numerals indicate like elements throughout. Certain terminology is used herein for convenience only and is not to be taken as a limitation on the present invention. The following describes preferred embodiments of the present invention. However, it should be understood, based on this disclosure, that the invention is not limited by the preferred embodiments described herein.

Lab-grown diamonds may have novel ornamental, optical, and/or other useful properties. Some of these properties may depend on the process and/or conditions used to grow the diamond as well as post-processing applied after the diamond is grown. For example, diamonds grown using Chemical Vapor Deposition (CVD) may grow into a cubic shape, whereas diamonds grown using High-Pressure, High-Temperature (HPHT) processes may grow into a cuboctahedron. Additional elements, other than carbon, may be introduced during growth for various purposes, such as coloring the diamond or altering its thermal or electrical properties.

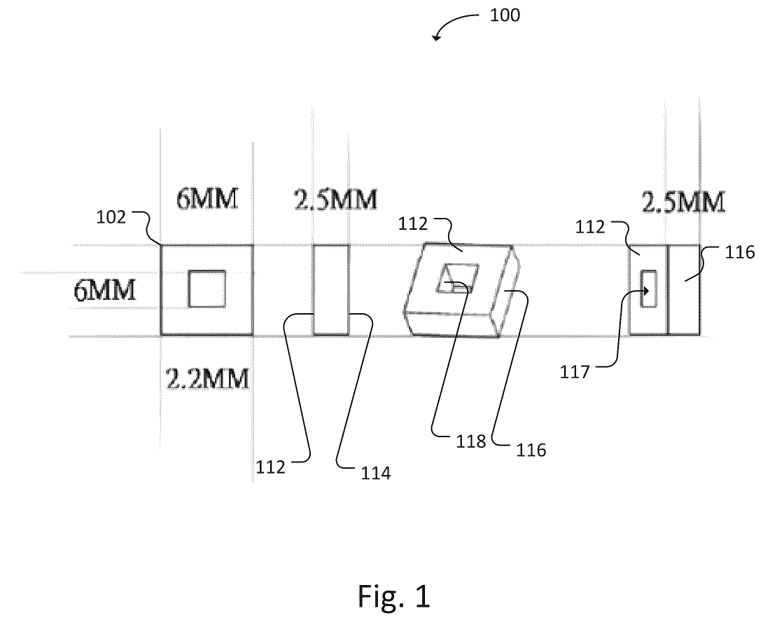

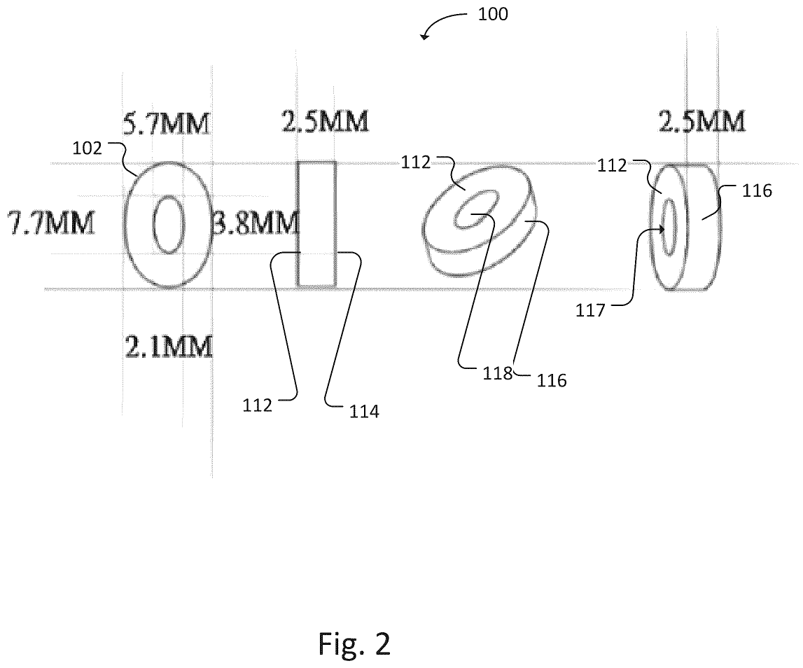

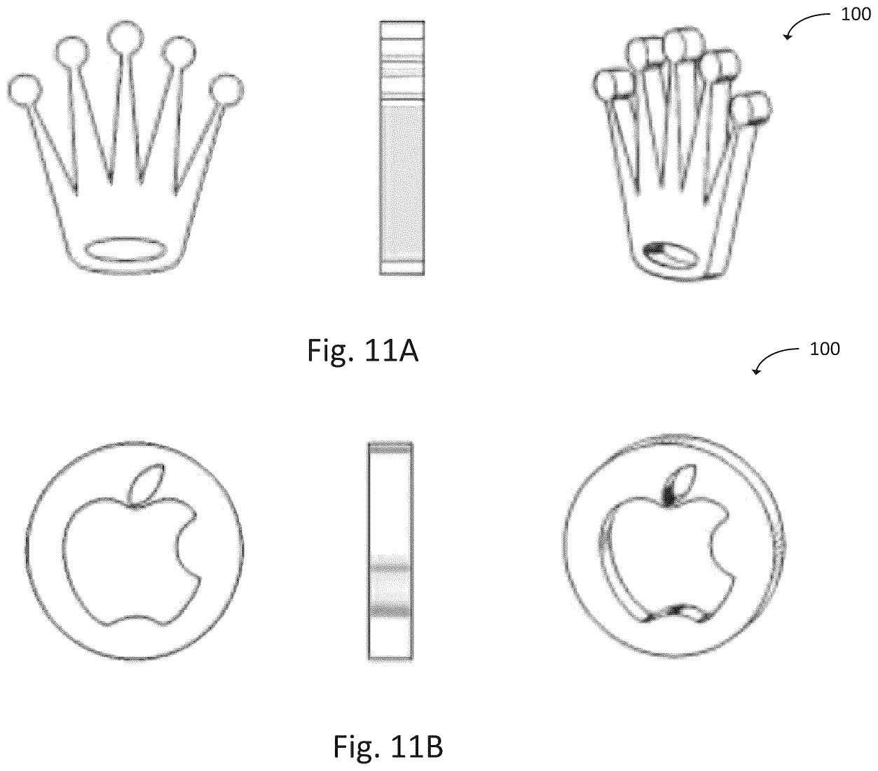

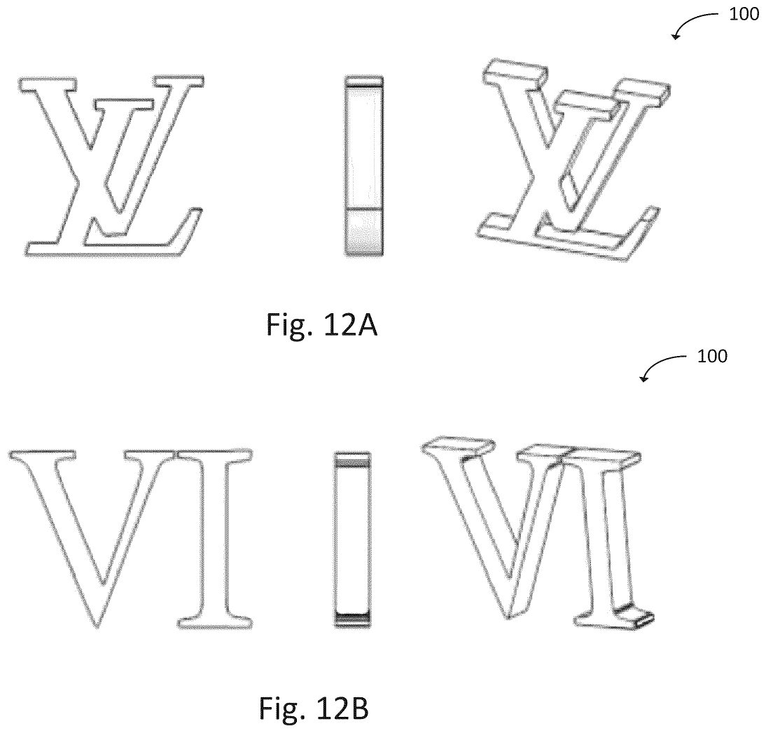

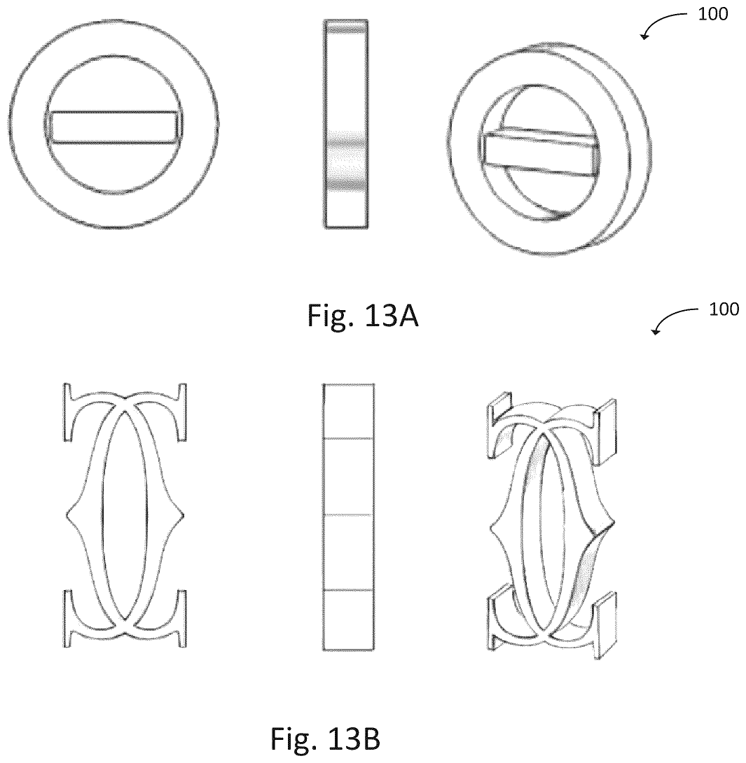

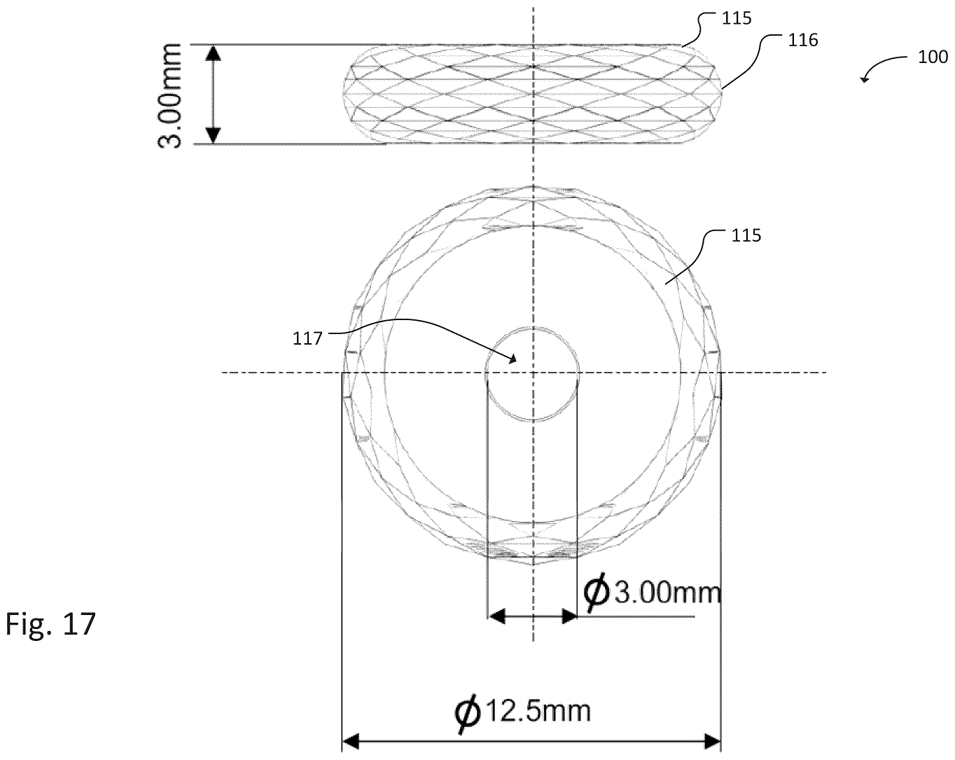

After growth, lab-grown diamonds may be shaped and/or polished into a jewel. Referring to FIG. 1, an example diamond jewel 100 is formed from a lab-grown diamond 102 and shaped to include parallel front 112 and rear 114 surfaces, each of which surface has the outline of a simple geometric shape, such as a circle, rectangle, regular octagon, any other polygon, etc. For example, in the embodiment shown in FIG. 1, the front 112 and rear 114 surfaces have a square outline. The embodiments shown in FIGS. 2-8 show other front 112 and rear 114 surfaces having other outlines. In some embodiments, the outline may be in the form of a symbol, such as one or more numerals, alphabetic characters, or the like, or a combination of symbols, rather than a geometric shape (e.g., FIGS. 12A, 12B, 13A). In some embodiments, the outline may be in the form of a logo, e.g., identifying a brand and/or organization (e.g., FIGS. 11A, 11B, 13B). Other outlines are also within the scope of this disclosure. As shown in FIGS. 1-17, the front 112 and rear 114 surfaces have the same outline. That is, the outlines have the same shape and size as each other. In other embodiments, the front 112 and rear 114 surfaces may have different outlines than each other. For example, the rear surface 114 may be a larger, e.g., scaled-up, version of the shape of the front surface 112 (or vice versa). In some embodiments, the outline of the front 112 and rear 114 surfaces have entirely different shapes and/or sizes. For example, the outline of the rear surface 114 may have a rectangular shape and the outline of the front surface 112 may be shaped as a symbol.

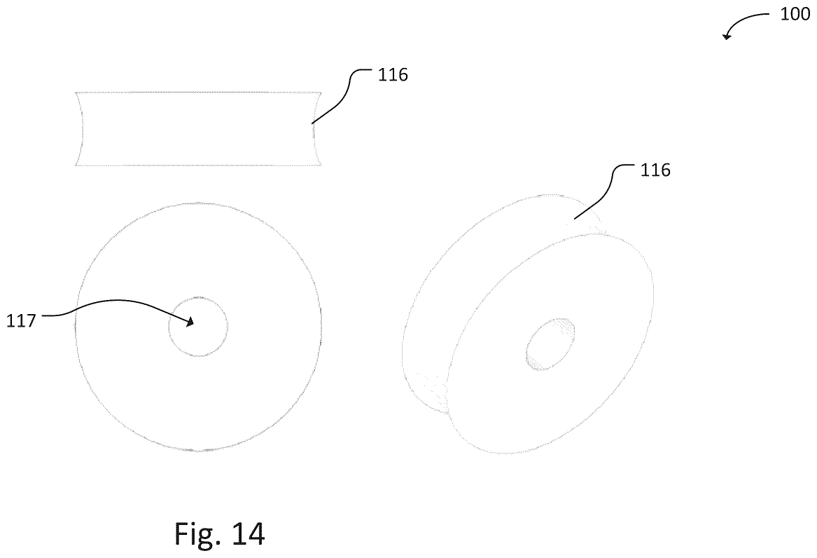

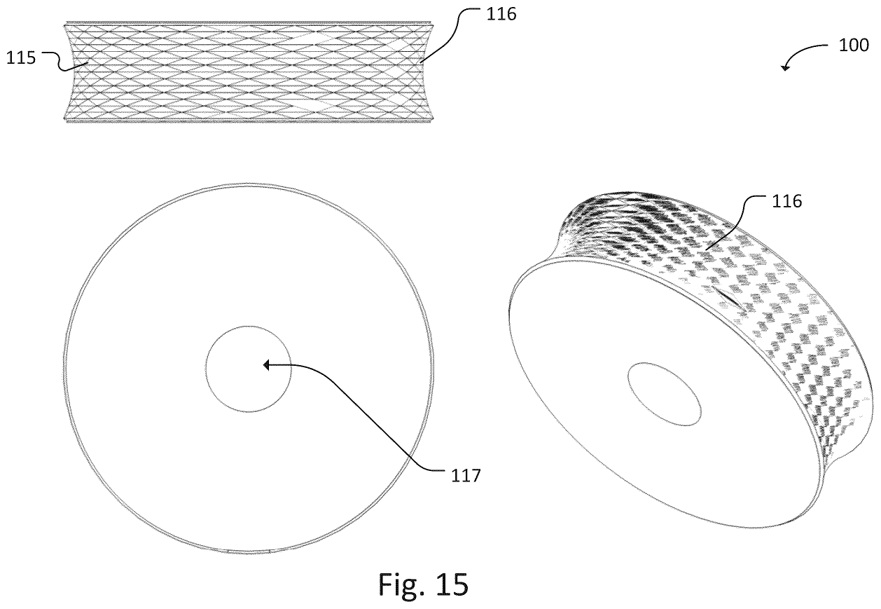

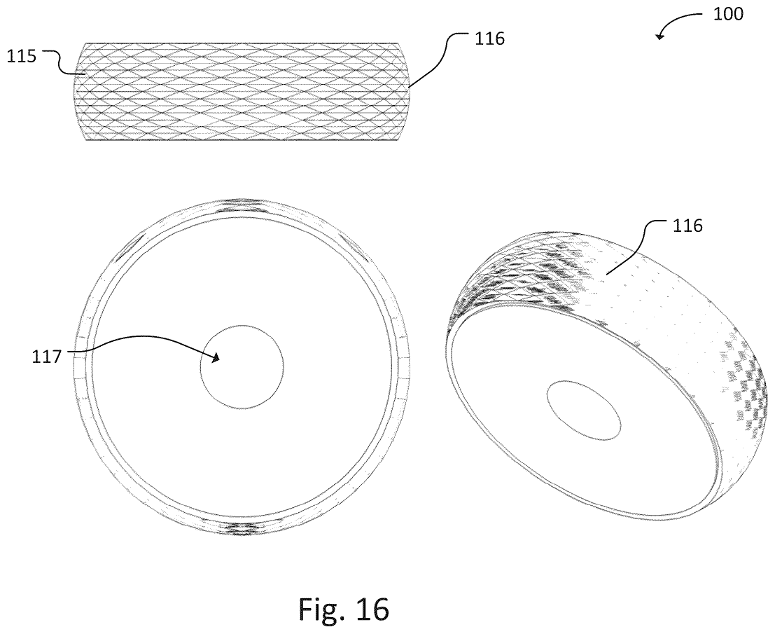

The example jewel 100 also includes one or more outer surfaces 116 that extend between the front 112 and rear 114 surfaces. As shown in FIGS. 1-13, the outer surfaces 116 are substantially perpendicular to both the front 112 and rear 114 surfaces. That is, the outer surfaces 116 meet each of the front 112 and rear 114 surfaces at substantially a right angle and are neither concave nor convex between the front 112 and rear 114 surfaces. In other embodiments, e.g., where the front 112 and rear 114 surfaces do not have the same size or shape, the outer surfaces 116 may meet one or both of the front 112 or rear 114 surfaces at an acute or obtuse angle, or even a variety of angles. Furthermore, in some embodiments the outer surfaces 116 are concave between the front 112 and rear 114 surfaces (e.g., as shown in FIG. 14) or convex (e.g., as shown in FIG. 16), or any combination of planar, concave, or convex, e.g., to achieve a desired optical or ornamental property. In some embodiments, some or all of the outer surfaces 116 are smoothly polished. In other embodiments, the outer surfaces 116 are left in an unpolished state or have one or more patterns applied (e.g., by laser etching) or are otherwise roughened after growth, e.g., to attenuate light transmission through the outer surfaces 116. In some embodiments, the diamond 102 is further shaped to introduce one or more beveled facets 115 (FIGS. 15-17), e.g., between an outer surface 116 and an adjacent front 112 and/or rear 114 surface. That is the beveled facet may be at another angle than the outer surface 116 or the adjacent front 112 and/or rear 114 surface. The shape of these facets 115 may depend on the shape of the outer surfaces 116. For example, in the case of rectangular outer surfaces 116, the facets 115 may also be rectangular. However, in the case of triangular outer surfaces 116, the facets 115 may also be triangular. These facets 115 may be smoothly polished or may have a pattern applied. Furthermore, additional facets 115 may be included between individual outer surfaces 116.

Some or all of the front 112 and/or rear 114 surfaces may also include smoothly polished faces, e.g., to enhance light transmission through the front and/or rear faces of the diamond 102. The example jewel 100 shown in FIG. 1 also includes a hole 117 extending through the diamond 102 from the front surface 112 to the rear surface 114. The hole 117 is defined by one or more inner surfaces 118 of the jewel 100. As shown, these inner surfaces 118 are substantially perpendicular to the front 112 and rear 114 surfaces. Thus, the inner surfaces 118 meet each of the front 112 and rear 114 surfaces at substantially a right angle. In other embodiments, the inner surfaces 118 may meet the front 112 and rear 114 surfaces at one or more acute or obtuse angles. And, as with the outer surfaces 116, the diamond 102 may include one or more beveled facets 115 between an inner surface 118 and an adjacent front 112 and/or rear 114 surface. As shown, each inner surface 118 is substantially parallel with corresponding outer surface 116. Also as with the outer surfaces 116, some or all of the inner surfaces 118 may be smoothly polished. In other embodiments, the inner surfaces 118 are left in an unpolished state or have one or more patterns applied (e.g., by laser etching) or are otherwise roughened after growth, e.g., to attenuate light transmission through the inner surfaces 118. In an embodiment having unpolished inner 118 and outer 116 surfaces, and where substantially all of the front 112 and rear 114 surfaces include polished faces, it may be possible to see clearly through the diamond 102, e.g., looking squarely at the front surface (or at an angle less than the critical angle of the diamond 102), but be unable to see through the outer surfaces 116 (or inner surfaces 118, if any). As discussed above, however, other configurations are possible, including polished inner surfaces 118 and/or outer surfaces 116. Furthermore, additional facets 115 may be included between individual inner surfaces 118. Other embodiments do not include a hole extending from the front surface 112 to the rear surface 114.

As shown, each of the front 112 and rear 114 surfaces are substantially flat and planar. In this configuration, the entirety (or at least substantially the entirety) of each of the front 112 and rear 114 surfaces are parallel to each other. In some embodiments, however, one or both surfaces 112, 114 may be somewhat concave or somewhat convex, e.g., to achieve a desired optical or ornamental property. For example, polished convex front 112 and rear 114 surfaces may provide a magnifying effect when looking through the diamond 102. Furthermore, as previously described, the diamond 102 may include one or more beveled facets 115 between an outer surface 116 and an adjacent front 112 and/or rear 114 surface. The transition from an outer surface 116 to the front 112 and/or rear 114 surface may include several facets 115. For example, these facets 115 may be configured to be similar to the facets of a brilliant-cut diamond that are located between the girdle and the table. Thus, the faceted region leading from an outer surface 116 to the front 112 and/or rear 114 surface may be locally convex. These multiple facets 115 may be approximately triangular or quadrilateral in shape, or may be any other shape that allows for the transition from an outer surface 116 to the front 112 and/or rear 114 surface.

Referring back to FIG. 1, a square embodiment 100 may weigh 1 carat, 2 carats, or any other suitable weight. For example, a 1-carat embodiment 100 may have a 6 mm square outline, with a 2.2 mm square hole 117 and a 2.5 mm thickness (i.e., the distance between the front 112 and rear 114 surfaces). A 2-carat embodiment 100 may have a 7 mm square outline, with a 2.8 mm square hole 117 and a 2.5 mm thickness. Other weights and dimensions are also within the scope of this disclosure.

Referring to FIG. 2, an oval embodiment 100 may weigh 1 carat, 2 carats, or any other suitable weight. For example, a 1-carat embodiment 100 may have a 7.7 by 5.7 mm oval outline, with a 3.8 by 2.1 mm oval hole 117 and a 2.5 mm thickness. A 2-carat embodiment 100 may have a 9 by 7 mm oval outline, with a 3.8 by 2.1 mm square hole 117 and a 2.5 mm thickness. Other weights and dimensions are also within the scope of this disclosure.

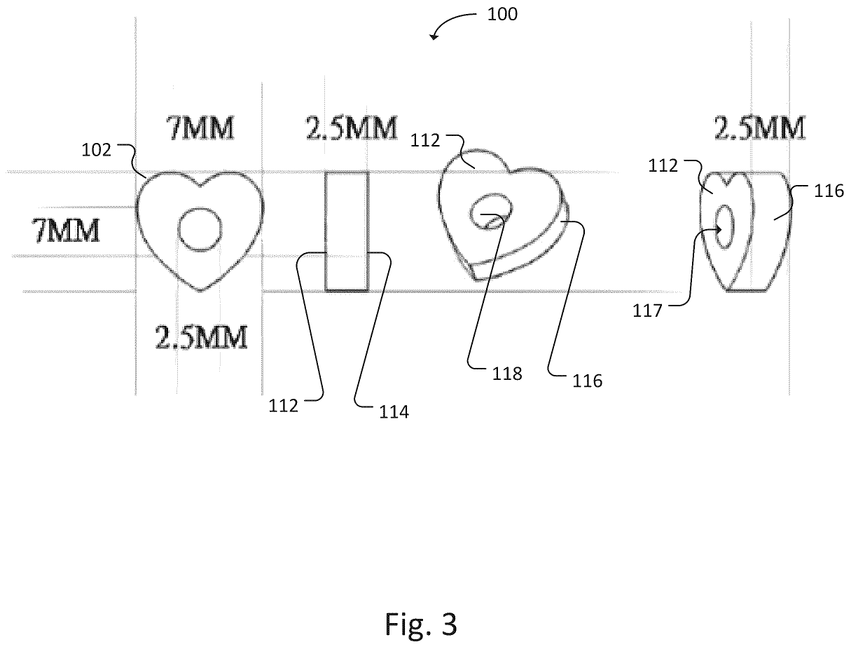

Referring to FIG. 3, a heart-shaped embodiment 100 may weigh 1 carat, 2 carats, or any other suitable weight. For example, a 1-carat embodiment 100 may have a heart-shaped outline having a 7 mm height and a 7 mm width, with a 2.5 mm round hole 117 and a 2.5 mm thickness. A 2-carat embodiment 100 may have a heart-shaped outline having a 8 mm height and a 8 mm width, with a 3 mm round hole 117 and a 2.5 mm thickness. Other weights and dimensions are also within the scope of this disclosure.

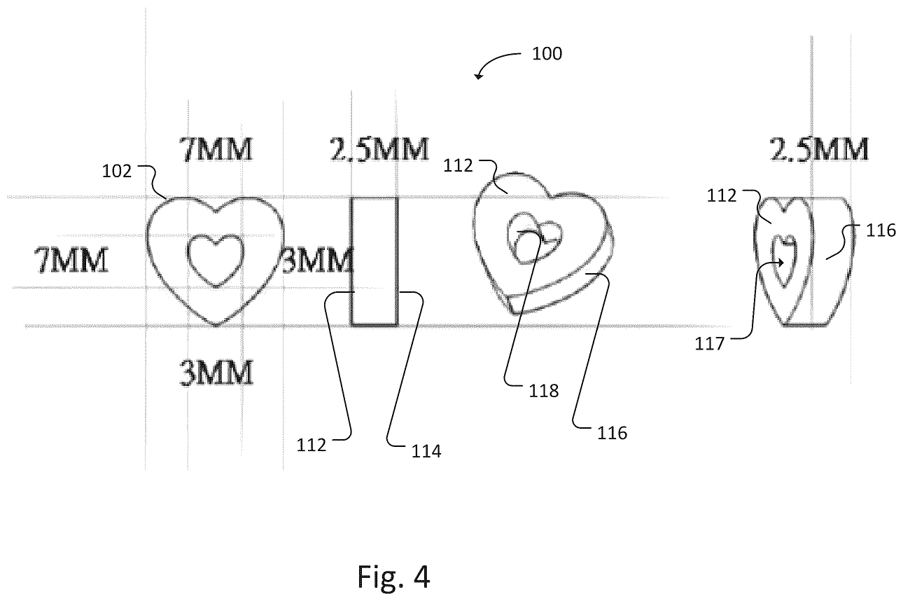

Referring to FIG. 4, a heart-shaped embodiment 100 may weigh 1 carat, 2 carats, or any other suitable weight. For example, a 1-carat embodiment 100 may have a heart-shaped outline having a 7 mm height and a 7 mm width, with a heart-shaped hole 117 having a 3 mm height and a 3 mm width, and a 2.5 mm thickness. A 2-carat embodiment 100 may have a heart-shaped outline having a 8 mm height and a 8 mm width, with a heart-shaped hole 117 having a 3.2 mm height and a 3.2 mm width, and a 2.5 mm thickness. Other weights and dimensions are also within the scope of this disclosure.

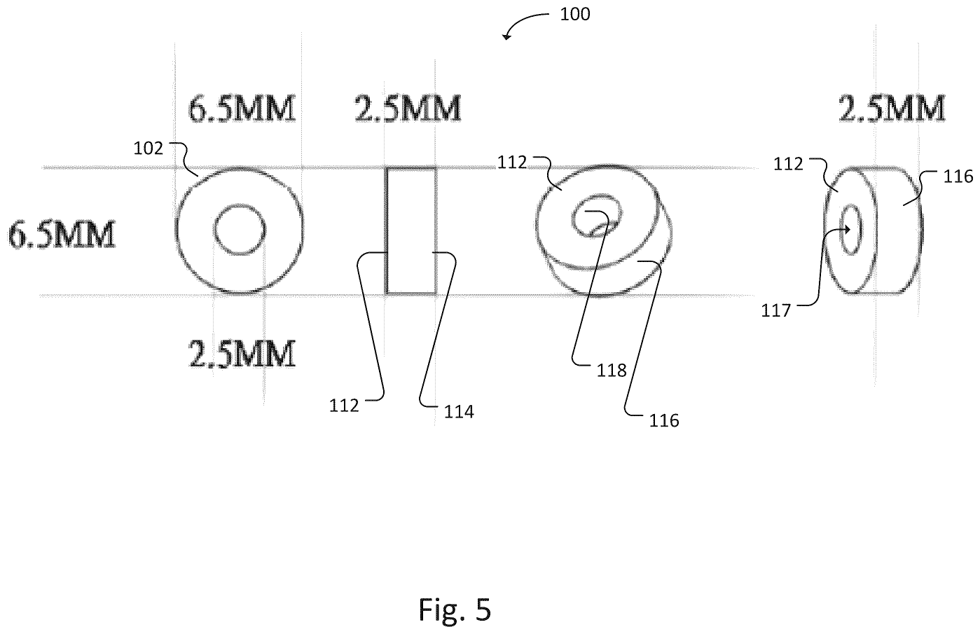

Referring to FIG. 5, a circular embodiment 100 may weigh 1 carat, 2 carats, or any other suitable weight. For example, a 1-carat embodiment 100 may have a circular outline having a 6.5 mm diameter, with a 2.5 mm circular hole 117, and a 2.5 mm thickness. A 2-carat embodiment 100 may have a circular outline having a 8 mm diameter, with a 3 mm circular hole 117, and a 2.5 mm thickness. Other weights and dimensions are also within the scope of this disclosure.

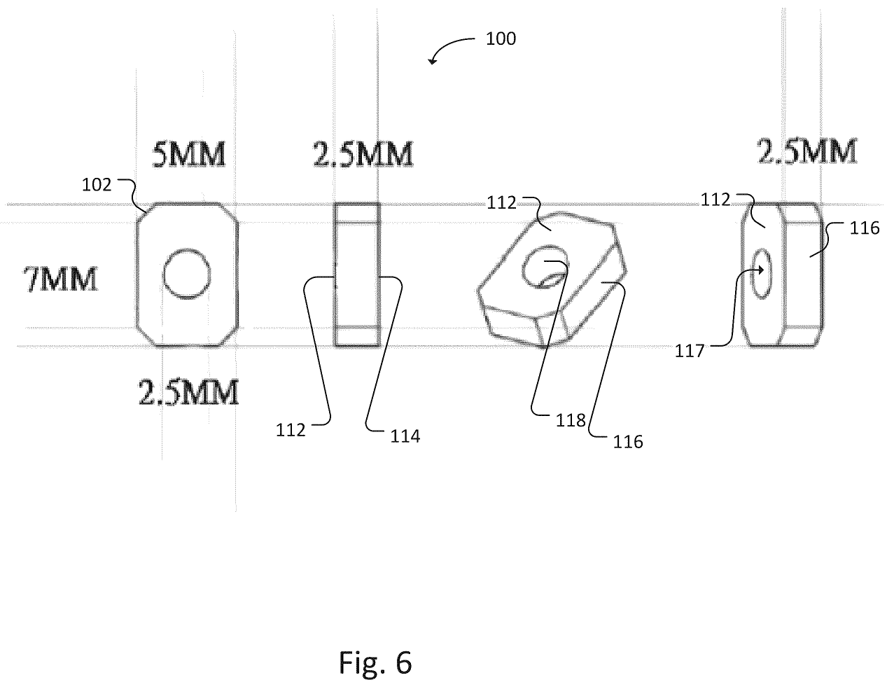

Referring to FIG. 6, an octagonal embodiment 100 may weigh 1 carat, 2 carats, or any other suitable weight. For example, a 1-carat embodiment 100 may have an irregular octagonal outline having a 7 mm height and a 5 mm width, with a circular hole 117 having a 2.5 mm diameter, and a 2.5 mm thickness. A 2-carat embodiment 100 may have an irregular octagonal outline having a 8.5 mm height and a 6.5 mm width, with a circular hole 117 having a 3 mm diameter, and a 2.5 mm thickness. Other weights and dimensions are also within the scope of this disclosure.

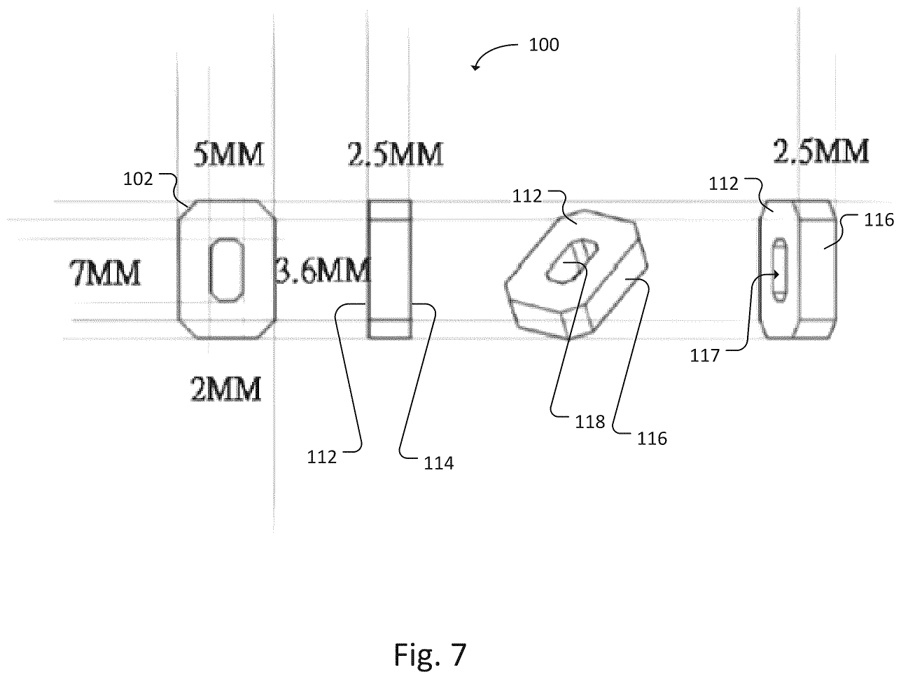

Referring to FIG. 7, an octagonal embodiment 100 may weigh 1 carat, 2 carats, or any other suitable weight. For example, a 1-carat embodiment 100 may have an irregular octagonal outline having a 7 mm height and a 5 mm width, with an irregular octagonal hole 117 having a 3.6 mm height and a 2 mm width, and a 2.5 mm thickness. A 2-carat embodiment 100 may have an irregular octagonal outline having a 8.5 mm height and a 6.5 mm width, with an irregular octagonal hole 117 having a 4 mm height and a 3 mm width, and a 2.5 mm thickness. Other weights and dimensions are also within the scope of this disclosure.

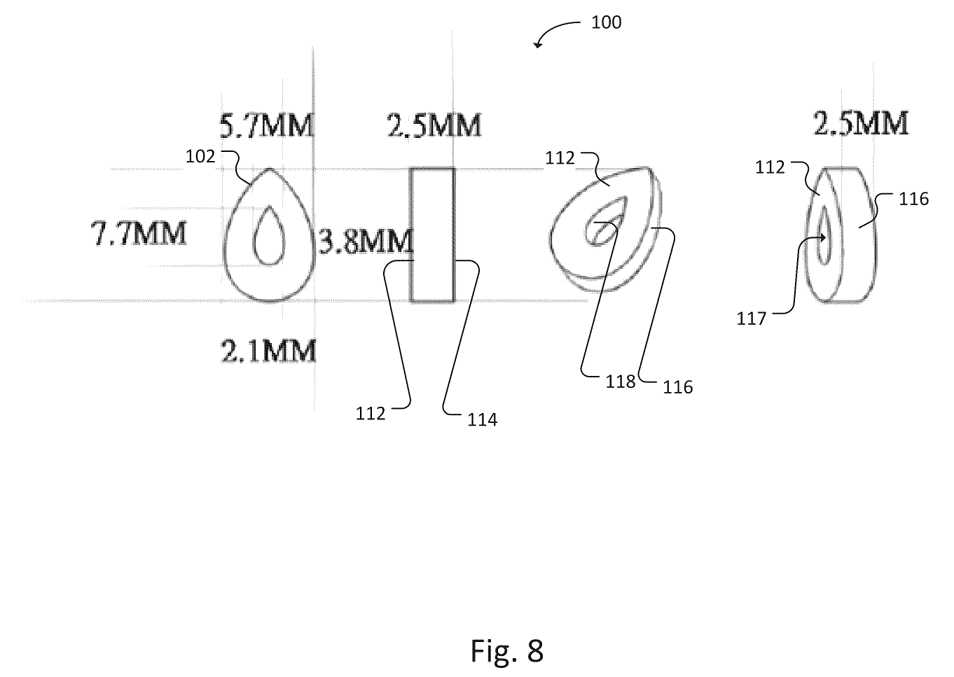

Referring to FIG. 8, a teardrop-shaped embodiment 100 may weigh 1 carat, 2 carats, or any other suitable weight. For example, a 1-carat embodiment 100 may have a teardrop-shaped outline having a 7.7 mm height and a 5.7 mm width, with a teardrop-shaped hole 117 having a 3.8 mm height and a 2.1 mm width, and a 2.5 mm thickness. A 2-carat embodiment 100 may have a teardrop-shaped outline having a 9 mm height and a 7.7 mm width, with a teardrop-shaped hole 117 having a 4.5 mm height and a 2.88 mm width, and a 2.5 mm thickness. Other weights and dimensions are also within the scope of this disclosure.

Although FIGS. 1-8 illustrate particular combinations of outlines and hole 117 shapes, embodiments having other combinations of geometric-shaped outlines and holes 117 shapes are also within the scope of this disclosure, as are embodiments that do not have a hole 117.

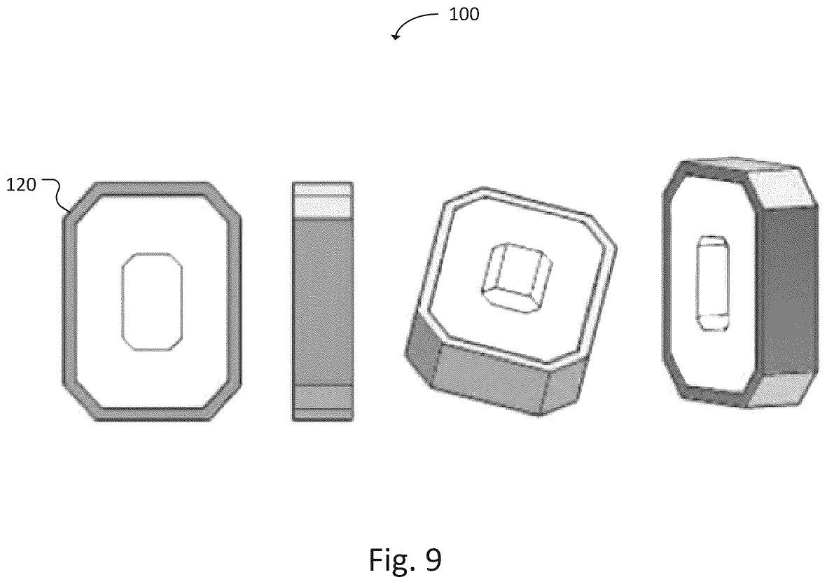

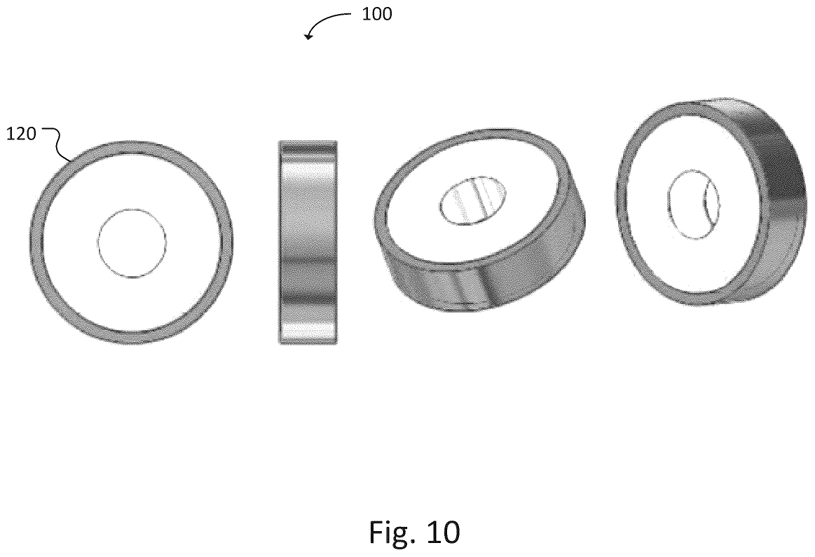

In another embodiment, at least one surface 112, 114, 116, 118 of the diamond 102, is covered with an outer layer 120. Referring to FIGS. 9 and 10, the outer surfaces 116 are covered with an outer layer 120 comprising a precious or semi-precious metal such as silver or gold. In other embodiments the outer layer 120 may be a more common metal, such as aluminum, or another material. The outer layer 120 may enhance the internal reflection of light within the diamond 102. Although FIGS. 9 and 10 illustrate octagonal and circular embodiments, respectively, the outer layer 120 may be applied to outer surfaces 116 of any of the embodiments described above or below in this disclosure. In some embodiments, the outer layer 120 covers inner surface 118, in addition to, or in lieu of, covering outer surfaces 116. In some embodiments, the outer layer 120 covers the front 112 and/or rear 114 surfaces.

In some embodiments, the diamond jewel 100 is configured to be self-supporting and may be used as a stand-alone novelty item or tchotchke. When equipped with a hole 117, the diamond jewel 100 may be used to secure a scarf or neckerchief. The diamond jewel 100 may also be incorporated as an ornamental component of a larger piece of jewelry. For example, the diamond jewel 100 may be a component of a ring, e.g., when mounted in a setting. Similarly, the diamond jewel 100 may be a component of a brooch, belt buckle, clasp (e.g., or a handbag), etc. In these and other contexts, the polished, substantially parallel front 112 and rear 114 surfaces (whether flat or concave/convex) may help to accentuate the material behind the diamond jewel 100. One or more diamond jewels 100 may be attached to a chain, either using hole 117 or a chain-attachment means such as a bale, to form a necklace pendant. In the necklace/pendant configuration, the diamond jewel 100 may help to accentuate the color of the wearer's clothing, or other material behind the diamond jewel 100.

When shaped as a symbol or logo (e.g., FIGS. 11A, 11B, 13B), the diamond jewel 100 may serve as a brand identifier. In some examples, the diamond jewel 100 has the shape of a logo or symbol. That is, the outline of the front and/or rear surfaces 112, 114 may be in the shape of a recognizable logo or symbol (e.g., FIGS. 11A, 13B). In other examples, the hole 117 is shaped like the logo/symbol (e.g., FIG. 11B). In some examples, a logo-shaped portion extends from one or more surfaces 112, 114, 116, 118 of the diamond jewel 100. For example, referring to FIG. 11B, instead of having a hole 117 shaped like the logo, the diamond jewel 100 may have a logo-shaped portion extending outward from the front surface 112. A diamond jewel 100 having a logo shape (or having a hole or a raised portion having a logo shape) may be applied to a suitable location of a branded product, such as the face of a luxury watch, the front of a premium laptop computer, the buckle of name-brand shoes, the clasp of a name-brand handbag, or the like.

These and other advantages of the present invention will be apparent to those skilled in the art from the foregoing specification. Accordingly, it will be recognized by those skilled in the art that changes or modifications may be made to the above-described embodiments without departing from the broad inventive concepts of the invention.

What is claimed is:

1. A diamond jewel comprising:
a lab-grown diamond having:
a front surface with an outline having a shape, the front surface comprising a polished front face;
a rear surface with an outline having the shape, the rear surface comprising a polished rear face, the rear surface parallel to the front surface; and
an outer surface extending between the front and rear faces, the outer surface comprising one or more outer faces, each of the one or more outer faces being perpendicular to the front and rear faces.

2. The diamond jewel of claim 1, wherein the lab-grown diamond further comprises one or more inner surfaces extending between the front and rear surfaces, the one or more inner surfaces defining a hole through the lab-grown diamond, each of the one or more inner surfaces being perpendicular to adjacent front and rear surfaces.

3. The diamond jewel of claim 2, wherein each of the one or more inner surfaces is parallel to at least one outer surface.

4. The diamond jewel of claim 1, wherein the shape comprises a geometric shape.

5. The diamond jewel of claim 1, wherein the shape comprises a symbol.

6. The diamond jewel of claim 1, wherein the lab-grown diamond is free of visible imperfections.

7. The diamond jewel of claim 1, further comprising a means for attaching a chain.

8. The diamond jewel of claim 1, wherein the lab-grown diamond further comprises one or more facets at a point where the front surface abuts the outer surface.

9. The diamond jewel of claim 1, wherein the lab-grown diamond is formed by a Chemical Vapor Deposition (CVD) process.

10. The diamond jewel of claim 1, wherein at least a portion of the one or more outer faces is unpolished.

11. The diamond jewel of claim 1, wherein at least one outer face is covered by an outer layer.

12. The diamond jewel of claim 11, wherein the outer layer comprises a precious metal.

13. A piece of jewelry comprising the diamond jewel of claim 1 in a setting.

14. The piece of jewelry of claim 13, wherein the piece of jewelry is a brooch.

15. The diamond jewel of claim 2, wherein the one or more inner surfaces define a heart-shaped hole.
